(19) United States
(12) Patent Application Publication
(10) Pub. No.: US 2024/0304582 A1
(43) Pub. Date: Sep. 12, 2024

(54) CIRCUIT SUBSTRATE IN CHIP PACKAGE AND METHOD FOR FORMING THE SAME

(71) Applicant: Xintec Inc., Taoyuan City (TW)

(72) Inventors: Wei-Ming CHIEN, Taoyuan City (TW); Po-Han LEE, Taipei City (TW); Tsang-Yu LIU, Zhubei City (TW)

(21) Appl. No.: 18/431,627

(22) Filed: Feb. 2, 2024

Related U.S. Application Data
(60) Provisional application No. 63/451,618, filed on Mar. 12, 2023.

(51) Int. Cl. H01L 23/00; H01L 23/498; H05K 1/18

(52) U.S. Cl. CPC H01L 24/16; H01L 23/49827; H01L 24/11; H01L 24/13; H05K 1/181; H01L 2224/11424; H01L 2224/11464; H01L 2224/13155; H01L 2224/13583; H01L 2224/13644; H01L 2224/13664; H01L 2224/16225; H01L 2924/1431

(57) ABSTRACT

A circuit substrate in a chip package is provided. The circuit substrate includes first and second insulating layers covering opposite first and second surfaces of the semiconductor substrate, respectively. The circuit substrate also includes first and second pads disposed in the first and second insulating layers, respectively, and laterally separated from an opening that extends from the first surface to the second surface of the semiconductor substrate. The circuit substrate further includes first and second under bump metallization (UBM) layers disposed on the first and second pads, respectively. The first UBM layer has a surface protruding above the first insulating layer, and the second UBM layer extends from the second pad onto the second insulating layer, and is partially recessed into the second insulating layer to form a concave surface.

### CROSS REFERENCE TO RELATED APPLICATIONS

This application claims the benefit of U.S. Provisional Application No. 63/451,618, filed Mar. 12, 2023, the entirety of which is incorporated by reference herein.

### BACKGROUND OF THE INVENTION

### Field of the Invention

The invention relates to s package technology, and in particular to a circuit substrate with a double-sided electrical connection structure in a chip package and a method for forming the same.

### Description of the Related Art

Optoelectronic devices are widely used in electronic products such as desktops, laptops, tablet computers, mobile phones, digital cameras, digital video recorders, and mobile phones. The chip package process is an important step in the fabrication of an electronic product. Chip packages not only protect sensing chips from outside environmental contaminants, but they also provide electrical connection paths between the electronic elements inside and those outside of the chip packages.

As the demand for electronic products increases, the number of input/output (I/O) pads of chips within a chip package also increases significantly. It is a challenge to use package technologies in order to smoothly mount the high-density input/output (I/O) pads of the chip within the chip package onto an external circuit board (for example, a printed circuit board) or onto other electronic devices or electronic modules having input/output (I/O) pads of different sizes.

Accordingly, there is a need for a circuit board in a chip package and a method for forming the same that are capable of eliminating or mitigating the aforementioned problems.

### BRIEF SUMMARY OF THE INVENTION

An embodiment of the present disclosure provides a circuit board in a chip package. The circuit board includes a semiconductor substrate having a first surface and a second surface opposite to the first substrate, and having at least one opening extending from the first surface to the second surface. The circuit board also includes a first insulating layer and a second insulating layer covering the first surface and the second surface of the semiconductor substrate, respectively. The circuit board further includes a first pad and a second pad disposed in the first insulating layer and the second insulating layer, respectively, and laterally separated from the opening. In addition, the circuit board includes a first under-bump metallization layer and a second under-bump metallization layer disposed on the first pad and the second pad, respectively. The first under-bump metallization layer is surrounded by the first insulating layer and has a surface protruding from the first insulating layer. The second under-bump metallization layer extends from the second pad onto the second insulating layer and is partially recessed into the second insulating layer to form a concave surface. The width of the second under-bump metallization layer is greater than the width of the first under-bump metallization layer.

An embodiment of the present disclosure provides a method for forming a circuit board in a chip package. The method includes providing a semiconductor substrate having a first surface and a second surface opposite to the first surface and forming at least one first pad, at least one first under-bump metallization layer and a first insulating layer on the first surface of the semiconductor substrate. The first pad is formed in the first insulating layer, and the first under-bump metallization layer is formed on the first pad and has a surface protruding from the first insulating layer. The method also includes forming at least one opening in the semiconductor substrate. The opening extends from the second surface to the first surface of the semiconductor substrate. The method further includes forming at least one second pad, at least a second under-bump metallization layer and a second insulating layer on the second surface of the semiconductor substrate. The second pad is formed in the second insulating layer, and the second under-bump metallization layer extends from the second pad onto the second insulating layer and is partially recessed into the second insulating layer to form a concave surface. The width of the second under-bump metallization layer is greater than the width of the first under-bump metallization layer.

### BRIEF DESCRIPTION OF THE DRAWINGS

The present disclosure can be more fully understood by reading the subsequent detailed description and examples with references made to the accompanying drawings, wherein:

FIGS. 1A to 1J illustrate cross-sectional views of a method for forming a circuit board in a chip package in accordance with some embodiments.

FIG. 2 is a cross-sectional view of a circuit board in a chip package in accordance with some embodiments.

FIG. 3 is a cross-sectional view of a chip package mounted on a printed circuit board in accordance with some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A semiconductor device structure according to the embodiments of the present disclosure may be implemented to various electronic components of integrated circuits including active or passive devices or digital or analog circuits. For example, the semiconductor device structure is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of a plurality of wafers having integrated circuits.

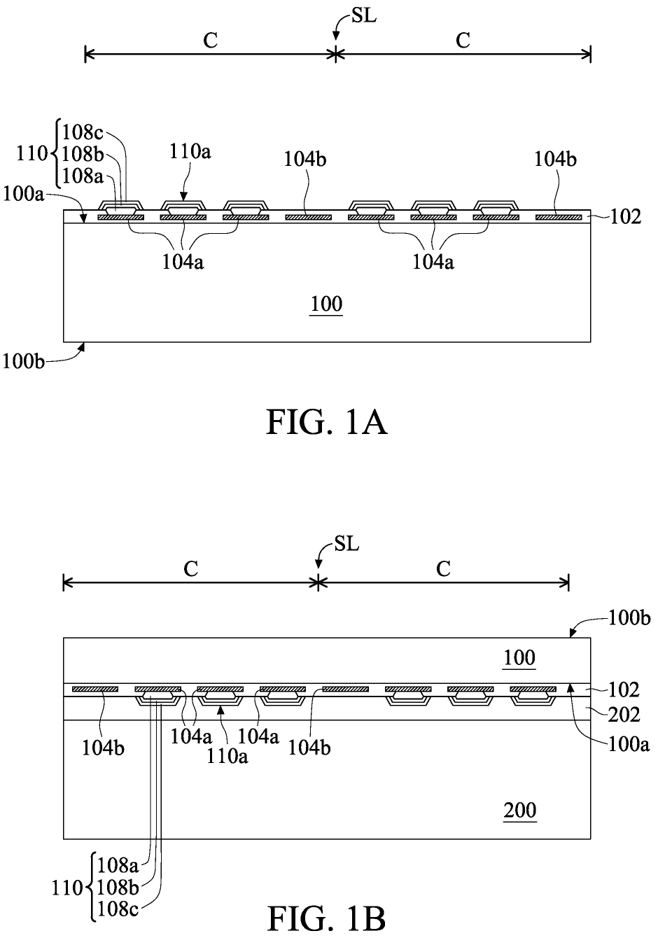

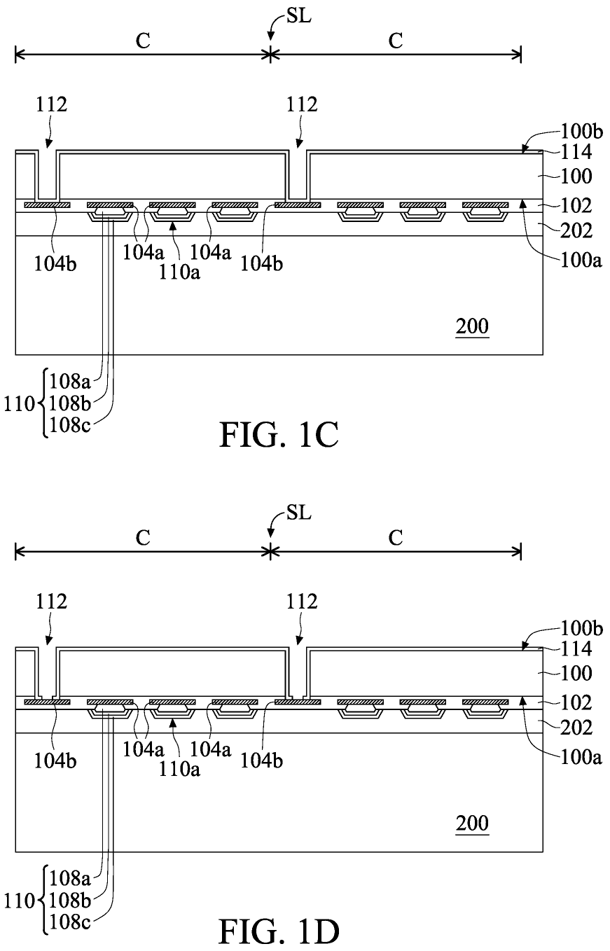

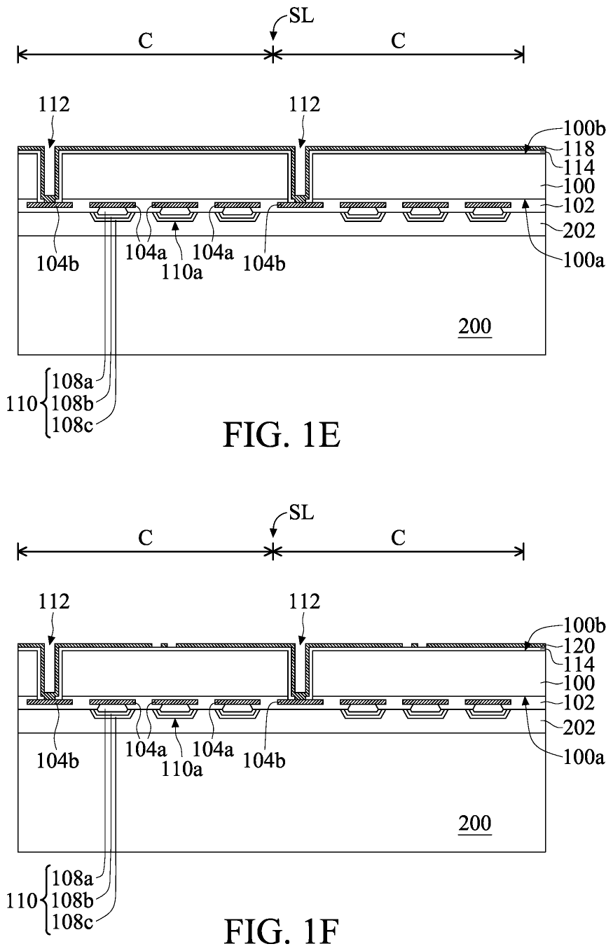

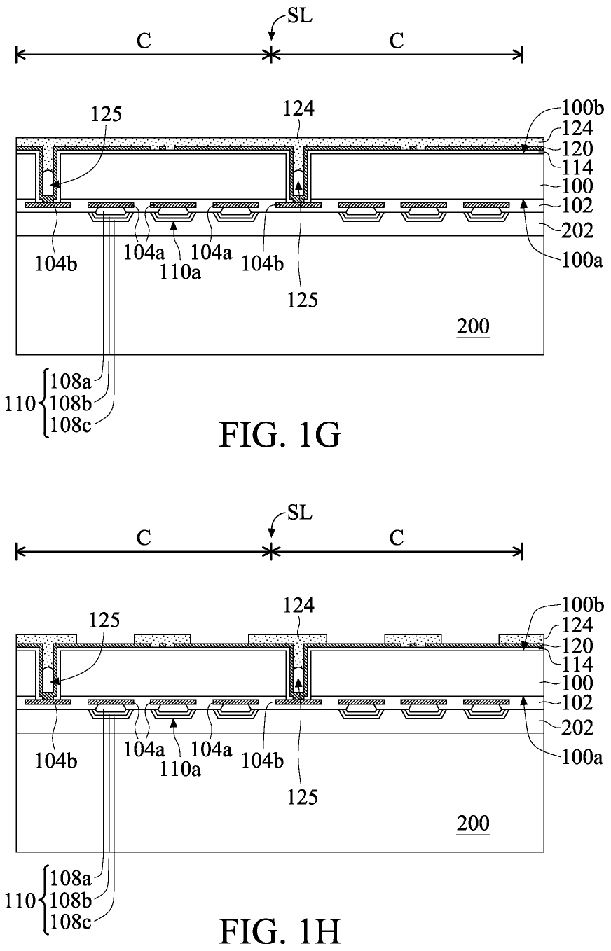

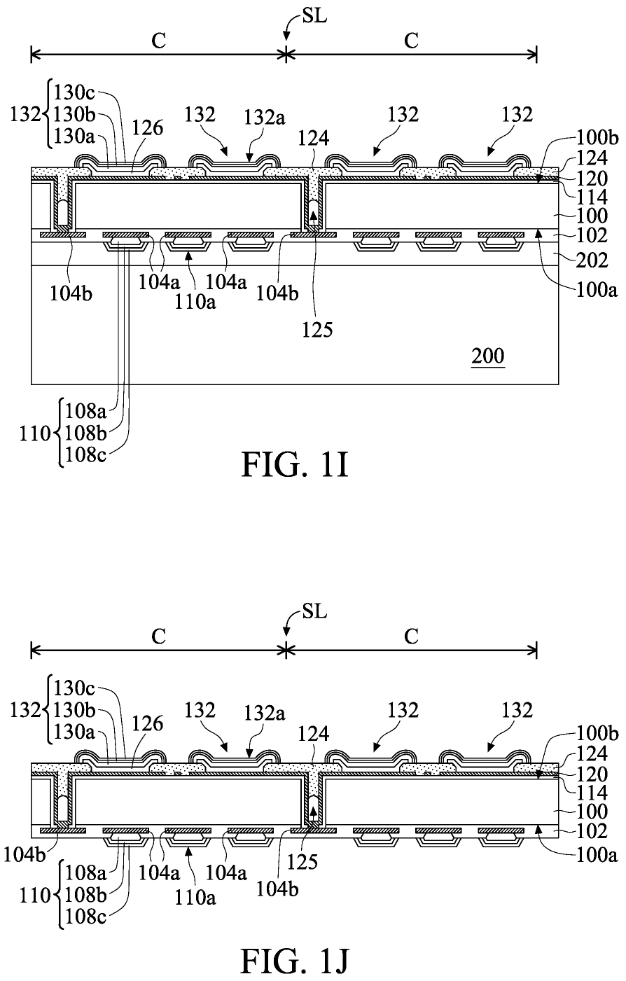

FIGS. 1A to 1J are cross-sectional views of a method for forming a circuit board 10 in a chip package in accordance with some embodiments. In some embodiments, the chip package is implemented with a front side illumination (FSI) sensing device. However, in other some embodiments, the chip package may also be implemented with a back side illumination (BSI) sensing device.

Referring to FIG. 1A, a substrate 100 is provided. The substrate 100 has a first surface 100a (e.g., an upper surface) and a second surface 100b (e.g., a lower surface) opposite to the first surface 100a. The substrate 100 also has chip regions and a scribe line region surrounding these chip regions and separating adjacent chip regions. For simplified the diagram, only two complete chip regions C are depicted, as well as a scribe line region SL separating these chip regions C. In some embodiments, the substrate 100 is a silicon wafer to facilitate wafer-level package processes. In other some embodiments, the substrate 100 is a silicon substrate or another semiconductor substrate. In some embodiments, the substrate 100 of the chip region C includes a circuit (not shown), and signal inputs and outputs are carried out through subsequently formed pads.

Afterwards, an insulating layer 102, one or more pads 104a, one or more pads 104b, and an under-bump metallization layer 110 corresponding to each of the pads 104a are formed on the first surface 100a of the substrate 100. More specifically, the insulating layer 102 formed on the first surface 100a may include an interlayer dielectric (ILD) layer, an inter-metal dielectric (IMD) layer, a passivation layer, or a combination thereof. For simplified the diagram, only a flat layer is depicted. Moreover, the insulating layer 102 may include an inorganic material such as silicon oxide (e.g., SiO₂), silicon nitride, silicon oxynitride, metal oxides, or a combination of thereof or another suitable insulating material. The pads 104a and 104b are formed in the insulating layer 102, and the under-bump metallization layer 110 is formed on and electrically connected to the pad 104a. It will be appreciated that the number of pads 104a and 104b depends on the design demands and is not limited to the embodiments shown in FIG. 1A.

In some embodiments, the pads 104a having under-bump metallization layers 110 on their upper surfaces serve as input/output (I/O) pads. The pads 104b do not serve as the input/output pads, and therefore their upper surface are not exposed from the insulating layer 102. In some embodiments, the pads 104a and 104b may be a single layer or have a multi-layer structure. For example, the pads 104a may be a single layer and the pads 104b may have a multi-layer structure. For simplified the diagram, only the pads 104a and 104b with a single layer structure are depicted as an example. The pads 104a and 104b may include a metal material, such as copper, aluminum, a combination thereof, or another suitable pad material.

In some embodiments, a portion of the under-bump metallization layer 110 protrudes above the insulating layer 102, so that the under-bump metallization layer 110 has a surface 110a protruding from the insulating layer 102. The other portions of the under-bump metallization layer 110 are surrounded by the insulating layer 102. In some embodiments, the under-bump metallization layer 110 has a multi-layer structure and includes a nickel layer 108a, a palladium layer 108b, and a gold layer 108c. The nickel layer 108a is in direct contact with the pad 104a. The palladium layer 108b and the gold layer 108c are successively stacked on the nickel layer 108a. In some embodiments, the upper surface of the nickel layer 108a is higher than the upper surface of the insulating layer 102, and the palladium layer 108b and the gold layer 108c conformally cover the upper surface of the nickel layer 108a and are disposed entirely on the upper surface of the insulating layer 102. As a result, the gold layer 108c has a convex upper surface. The under-bump metallization layer 110 formed by the nickel layer 108a, the palladium layer 108b, and the gold layer 108c may be formed by an electroless nickel electroless palladium immersion gold (ENEPIG) process.

Referring to FIG. 1B, a carrier substrate 200 is provided. The carrier substrate 200 may be made of silicon, glass, ceramic, or a combination of substrate materials, and may have a wafer shape to facilitate wafer-level package processes. For example, the carrier substrate 200 is a glass wafer and serves as a temporary support structure in the fabrication of the circuit board 10. Next, an adhesive layer 202 is formed on the carrier substrate 200. In some embodiments, the adhesive layer 202 may be made of a light-to-heat conversion (LTHC) material or another suitable material. Afterwards, the substrate 100 is bonded to the carrier substrate 200 by the adhesive layer 202. Thereafter, a thinning process (e.g., an etching process, a milling process, a grinding process, or a polishing process) is performed on the second surface 100b of the substrate 100 to reduce the thickness of the substrate 100.

Referring to FIG. 1C, one or more openings 112 are formed in the substrate 100 and extend from the second surface 100b of the substrate to the first surface 100a. In some embodiments, the openings 112 are formed in the substrate 100 of each chip region C by a lithography process and an etching process (e.g., a dry etching process, a wet etching process, a plasma etching process, a reactive ion etching process, or another suitable process). The openings 112 are substantially vertically aligned to the pads 104b in the insulating layer 102 of each chip region C and are laterally spaced apart from the pads 104a. Further, the openings 112 extend through the substrate 100 and into the insulating layer 102 to expose the pads 104b. Afterwards, an insulating liner 114 may be conformally formed on the second surface 100b of the substrate 100 by a deposition process (e.g., a thermal oxidation process, a coating process, a physical vapor deposition process, a chemical vapor deposition process, or another suitable process). The insulating liner 114 is also conformally deposited on the sidewall surfaces and the bottom surface of the openings 112. In some embodiments, the insulating lining 114 may include an inorganic material (e.g., silicon oxide, silicon nitride, silicon oxynitride, metal oxide, or a combination thereof) or another suitable insulating material. Next, the insulating lining 114 is patterned to expose the lower surface of the pads 104b located at the bottom of the opening 112, as shown in FIG. 1D.

Referring to FIGS. 1E to 1F, a patterned redistribution line layer 120 may be formed on the insulating liner 114 by successively performing an deposition process (e.g., a coating process, a physical vapor deposition process, a chemical vapor deposition process, an electroplating process, an electroless plating process, or another suitable process), a lithography process, and an etching process. For example, a conductive layer 118 is formed conformally on the insulating liner 114 by an electroplating process. The conductive layer 118 is also conformally formed on the insulating liner 114 on the sidewall surfaces and bottom surface of the openings 112 and is in directly an electrically contact with or in indirectly and electrically connected to the exposed pads 114b via the openings 112, as shown in FIG. 1E. In some embodiments, the conductive layer 118 includes aluminum, titanium, tungsten, copper or a combination thereof or another suitable conductive material. Afterwards, the conductive layer 118 is patterned by successively performing a lithography process and an etching process to form the redistribution layer 120, as shown in FIG. 1F.

In some embodiments, the redistribution layer 120 is formed on the second surface 100b of the substrate 100 and conformally extends to the sidewall surfaces and the bottom surface of the openings 112. The redistribution layer 120 is electrically isolated from the substrate 100 by the insulating lining 114, and is directly or indirectly electrically connected to exposed pads 114b via the openings 112. As a result, the redistribution layer 120 in each opening 112 forms a substrate through-substrate via (TSV).

Referring to FIGS. 1G to 1J, an insulating layer 124, one or more pads 126, and an under-bump metallization layer 132 corresponding to each of the pads 126 are formed on the second surface 100b of the substrate 100. As shown in FIG. 1G, an insulating layer 124 (or referred to as passivation layer) is formed on the lower surface 100b of the substrate 100 by a deposition process and fills the openings 112 to cover the redistribution layer 120 that includes the through-substrate vias. In some embodiments, the insulating layer 124 only partially fills each of the openings 112, so that a hole 125 is formed between the redistribution layer 120 and the insulating layer 124 within the openings 112. In some embodiments, the interface between the hole 125 and the insulating layer 124 has an arcuate contour. In other some embodiments, the insulating layer 124 may fully fill the openings 112. The insulating layer 124 may include an epoxy resin, a solder mask, an organic polymer material (e.g., polyimide resin, butylcyclobutene, parylene, polynaphthalenes, fluorocarbons or acrylates), or another suitable insulating materials.

Next, one or more openings may be formed in the insulating layer 124 on the second surface 100b of the substrate 100 by a lithography process and an etching process to expose a portion of the redistribution layer 120, as shown in FIG. 1H.

Afterwards, as shown in FIG. 1I, the pads 126 and the under-bump metallization layer 132 are successively formed in the openings in the insulating layer 124, so that the under-bump metallization layer 132 is electrically connected to the underlying exposed redistribution layer 120 via the pads 126. As a result, the pads 104b in the insulating layer 102 are electrically connected to the pads 126 in the insulating layer 124 via the redistribution layer 120 (which includes the through-substrate vias). It will be appreciated that the number of pads 126 depends on the design demands and is not limited to the embodiments shown in FIG. 1I.

In some embodiments, the pads 126 may be a single layer or have a multi-layer structure. For example, the pads 126 are a single layer. The pads 126 may include a metal material, such as copper, aluminum, a combination thereof, or another suitable pad material. Unlike the pads 104a and 104b, the pads 126 are located in and partially extend on the insulation layer 124. In some embodiments, the pad 126 may also serve as a portion of the under-bump metallization layer that is subsequently formed thereon.

In some embodiments, similar to the under-bump metallization layers 110 (shown in FIG. 1A), the under-bump metallization layers 132 have a multi-layer structure and include a nickel layer 130a, a palladium layer 130b, and a gold layer 130c. The nickel layer 130a may be in direct contact with the pad 126, and the palladium layer 130b and the gold layer 130c are successively stacked on the nickel layer 130a. In some embodiments, the under-bump metallization layer 132 extends from the pad 126 onto the insulating layer 124 and is partially recessed into the insulating layer 124 to form a concave surface 132a. As a result, the nickel layer 130a, the palladium layer 130b, and the gold layer 130c all have concave upper surfaces. The under-bump metallization layer 132 formed by the nickel layer 130a, the palladium layer 130b, and the gold layer 130c may also be formed by an ENEPIG process.

In some embodiments, the width of the under-bump metallization layer 132 is greater than the width of the under-bump metallization layer 110. As a result, conductive structures (e.g., solder balls, bumps, or conductive posts) of different sizes can be formed on two opposing surfaces (e.g., first surface 100a and second surface 100b) of the substrate 100 via the under-bump metallization layers 110 and 132. Accordingly, the two opposing surfaces of the substrate 100 can be electrically connected to devices or electronic components having input/output (I/O) pads of different sizes. For example, the under-bump metallization layers 110 on the first surface 100a of the substrate 100 may be electrically connected to a semiconductor chip, and the under-bump metallization layers 132 on the second surface 100a of the substrate 100 are electrically connected to a printed circuit board.

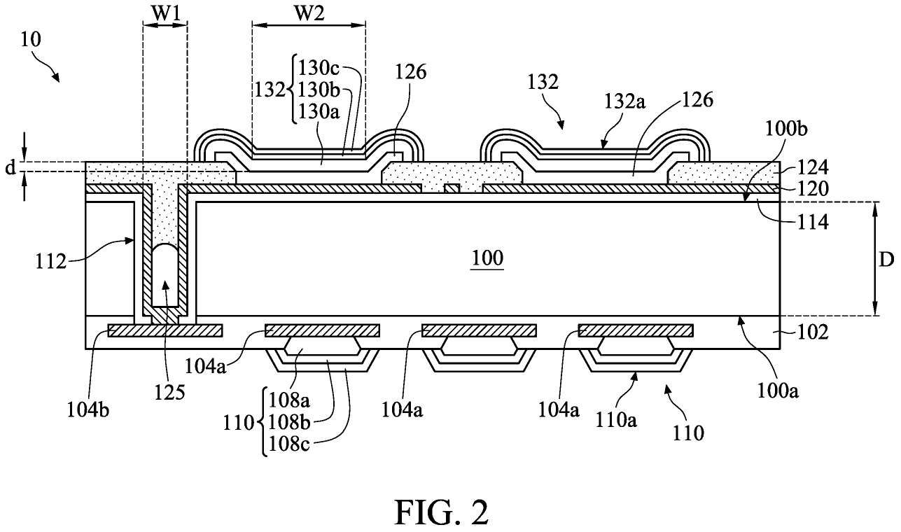

After forming the under-bulk metal layer 132, a de-bonding process is performed by irradiating the adhesive layer 202 with laser light or ultraviolet (UV) light. Due to the heat generated by the laser light or the UV light, the adhesive layer 202 formed by the light-to-heat conversion (LTHC) material decomposes, and thus the carrier substrate 200 is removed from the structure shown in FIG. 1I, as shown in FIG. 1J. Afterwards, the substrate 100 is diced along the scribe line region SL. For example, the dicing process may be performed using a dicing saw or laser. After the dicing process, an individual circuit substrate 10 may be formed, as shown in FIG. 2.

Referring to FIG. 2, the circuit substrate 10 includes: a substrate 100, insulating layers 102 and 124, pads 104a, 104b, and 126, through-substrate vias formed of a redistribution layer 120, and under-bump metallization layers 110 and 132. In some embodiments, the substrate 100 has a first surface 100a and a second surface 100b opposite to the first surface 100a. Moreover, the substrate 100 has at least one opening 112 extending from the first surface 100a to the second surface 100b. The ratio of the width W1 of the opening 112 to the thickness D of the substrate 100 is in a range from about 1:1 to about 1:3.

In some embodiments, the insulating layers 102 and 124 cover the first and second surfaces 100a and 100b of the substrate 100, respectively. Further, the insulating layer 124 partially fills an opening 112 in the substrate 100 to form a hole 125 between the through-substrate via and the insulating layer 124 in the opening 112.

In some embodiments, the pads 104a and 104b are disposed in the insulating layer 102, and the pads 126 are disposed in the insulating layer 124. The pads 104a and 126 are laterally spaced apart from the openings 112 in the substrate 100 and the through-substrate vias in those openings 112. The pad 104b in the insulating layer 102 is substantially vertically aligned with and electrically connected to the through-substrate via in the substrate 100. Further, the through-substrate vias extend from the openings 112 in the substrate to between the catch pad 126 and the substrate 100 by the redistribution layer 120 and are electrically connected to the pads 126.

In some embodiments, the under-bump metallization layers 110 and 132 are disposed on the pads 104a and 126, respectively. Further, the width of the under-bump metallization layer 132 is greater than the width of the under-bump metallization layer 110. In addition, the under-bump metallization layers 110 and 132 have different upper surfaces. The under-bump metallization layers 110 have a surface 110a protruding from the insulating layer 102, while the under-bump metallization layer 132 is partially recessed into the insulating layer 124 to form a concave surface 132a. The under-bump metallization layer 132 forms a recess corresponding to the pad 126 since the under-bump metallization layer 132 is partially recessed into insulating layer 124. Further, the ratio of the depth d of the recess to the width W2 of the recess is in a range from about 1:8 to about 1:30.

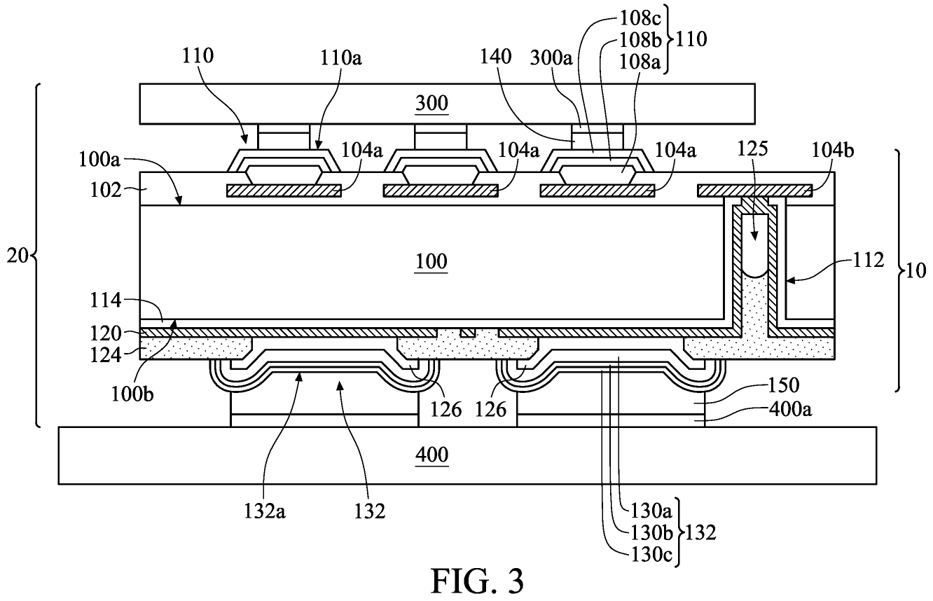

Referring to FIG. 3, a cross-sectional view of a chip package 20 mounted on a printed circuit board 400 in accordance with some embodiments is shown. In some embodiments, the chip package 20 includes a circuit substrate 10 (as shown in FIG. 2), a semiconductor chip 300, and conductive structures 140 and 150.

In some embodiments, the semiconductor chip 300 is disposed above the first surface 100b of the substrate 100 in the circuit substrate 10. The pads 300a of the semiconductor chip 300 are electrically connected to the under-bump metallization layers 110 in the circuit board 10 via the conductive structures 140. Further, the printed circuit board 400 is disposed above the second surface 100b of the substrate 100 in the circuit board 10. The pads 400a of the printed circuit board 400 are electrically connected to the under-bump metallization layers 132 in the circuit board 10 by the conductive structures 150. The width of the conductive structures 150 is also larger than the width of the conductive structures 140 for different sizes of the under-bump metallization layers 110 and 132. The conductive structures 140 and 150 may be solder balls, bumps, or conductive posts and include tin, lead, copper, gold, nickel, or a combination thereof.

In some embodiments, the semiconductor chip 300 is a sensing chip. In other some embodiments, the semiconductor chip 300 is a logic chip, a sensing chip, a memory chip, an application specific integrated circuit (ASIC) chip, or a system-on-chip (SoC). In some embodiments, the printed circuit board 400 is replaced with an electronic device or an electronic module.

According to the foregoing embodiments, the chip package includes a circuit substrate therein, and the circuit substrate has under-bump metallization layers with different sizes formed on its upper and lower surfaces. Accordingly, the high-density input/output (I/O) pads in the chip in the chip package can be smoothly mounted on an external circuit board (e.g., a printed circuit board) or other electronic device or electronic module having input/output (I/O) pads with different sizes.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit substrate in a chip package, comprising:
a semiconductor substrate having a first surface and a second surface opposite to the first substrate, wherein the semiconductor substrate has at least one opening extending from the first surface to the second surface;
a first insulating layer and a second insulating layer covering the first surface and the second surface of the semiconductor substrate, respectively;
a first pad and a second pad disposed in the first insulating layer and the second insulating layer, respectively, and laterally separated from the opening; and
a first under-bump metallization layer and a second under-bump metallization layer disposed on the first pad and the second pad, respectively;
wherein the first under-bump metallization layer is surrounded by the first insulating layer and has a surface protruding from the first insulating layer;
wherein the second under-bump metallization layer extends from the second pad onto the second insulating layer and is partially recessed into the second insulating layer to form a concave surface; and
wherein a width of the second under-bump metallization layer is greater than a width of the first under-bump metallization layer.

2. The circuit substrate as claimed in claim 1, further comprising:
a third pad disposed in the first insulating layer and substantially vertical to the opening in the semiconductor substrate; and
a through-substrate via disposed in the opening in the semiconductor substrate and electrically connected to the third pad.

3. The circuit substrate as claimed in claim 2, wherein the through-substrate via extends from the opening in the semiconductor substrate to between the second pad and the semiconductor substrate, and is electrically connected to the second pad.

4. The circuit substrate as claimed in claim 1, wherein the second insulating layer partially fills the opening in the semiconductor substrate to form a hole between the through-substrate via and the second insulating layer in the opening.

5. The circuit substrate as claimed in claim 1, wherein a material of the first insulating layer is different from a material of the second insulating layer.

6. The circuit substrate as claimed in claim 5, wherein the first insulating layer comprises silicon oxide, and the second insulating layer comprises an organic insulating material.

7. The circuit substrate as claimed in claim 1, wherein the first under-bump metallization layer and the second under-bump metallization layer each comprise:
a nickel layer;
a palladium layer stacked on the nickel layer; and
a gold layer stacked on the palladium layer.

8. The circuit substrate as claimed in claim 1, wherein the chip package comprises:
a semiconductor chip disposed above the first surface of the semiconductor substrate; and
a first conductive structure electrically connected between the semiconductor chip and the first under-bump metallization layer.

9. The circuit substrate as claimed in claim 8, wherein the chip package further comprises a second conductive structure electrically connected to the second under-bump metallization layer.

10. The circuit substrate as claimed in claim 1, wherein a ratio of a width of the opening in the semiconductor substrate to a thickness of the semiconductor substrate is in a range from 1:1 to 1:3.

11. The circuit substrate as claimed in claim 1, wherein the second under-bump metallization layer that is partially recessed into the second insulating layer forms a recess corresponding to the second pad, and wherein a ratio of a depth of the recess to a width of the recess is in a range from 1:8. to 1:30.

12. A method for forming a circuit substrate in a chip package, comprising:
providing a semiconductor substrate having a first surface and a second 2 surface opposite to the first surface;
forming at least one first pad, at least one first under-bump metallization layer and a first insulating layer on the first surface of the semiconductor substrate, wherein the first pad is formed in the first insulating layer, and the first under-bump metallization layer is formed on the first pad and has a surface protruding from the first insulating layer;
forming at least one opening in the semiconductor substrate, wherein the opening extends from the second surface to the first surface of the semiconductor substrate; and
forming at least one second pad, at least a second under-bump metallization layer and a second insulating layer on the second surface of the semiconductor substrate, wherein the second pad is formed in the second insulating layer, and the second under-bump metallization layer extends from the second pad onto the second insulating layer and is partially recessed into the second insulating layer to form a concave surface;
wherein a width of the second under-bump metallization layer is greater than a width of the first under-bump metallization layer.

13. The method as claimed in claim 12, further comprising:
forming a third pad in the first insulating layer before forming the opening, wherein the third pad is substantially vertically aligned with the opening; and
forming a through-substrate via in the opening and electrically connected to the third pad.

14. The method as claimed in claim 12, wherein the through-substrate via extends from the opening to between the second pad and the semiconductor substrate, and is electrically connected to the second pad.

15. The method as claimed in claim 12, wherein the second insulating layer partially fills the opening to form a hole between the through-substrate via and the second insulating layer in the opening after forming the second insulating layer.

16. The method as claimed in claim 12, wherein the first insulating layer comprises silicon oxide, and the second insulating layer comprises an organic insulating material.

17. The method as claimed in claim 12, wherein the first under-bump metallization layer and the second under-bump metallization layer are formed by an electroless nickel electroless palladium immersion gold process.

18. The method as claimed in claim 12, wherein a ratio of a width of the opening in the semiconductor substrate to a thickness of the semiconductor substrate is in a range from 1:1 to 1:3.

19. The method as claimed in claim 17, wherein the second under-bump metallization layer that is partially recessed into the second insulating layer forms a recess corresponding to the second pad, and wherein a ratio of a depth of the recess to a width of the recess is in a range from 1:8. to 1:30.

20. The method as claimed in claim 17, further comprising:
forming a first conductive structure on the first under-bump metallization layer; and
forming a second conductive structure on the second under-bump metallization layer.
